(19) United States
(12) Patent Application Publication
(10) Pub. No.: US 2024/0043987 A1
(43) Pub. Date: Feb. 8, 2024

(54) Method to Manufacture Ruthenium Rotary Sputtering Target

(71) Applicant: Singapore Advanced Thin Film Material Private Limited, Singapore (SG)

(72) Inventors: Shuangming Zheng, Singapore (SG); Xiangyu Bai, Singapore (SG); Ruoyu Zhang, Singapore (SG); Yanbin Xia, Singapore (SG); Kok Tong Phang, Singapore (SG); Yusheng Wu, Singapore (SG)

(73) Assignee: Singapore Advanced Thin Film Material Private Limited, Singapore (SG)

(21) Appl. No.: 17/902,204

(22) Filed: Sep. 2, 2022

(30) Foreign Application Priority Data
Aug. 8, 2022 (CN) 202210943255.6

(51) Int. Cl. C23C 14/34; B22F 3/15; B22F 3/04; B22F 3/03

(52) U.S. Cl. CPC C23C 14/3414; B22F 3/15; B22F 3/04; B22F 3/03; B22F 2301/25

(57) ABSTRACT

The invention discloses a method for preparing a ruthenium rotary sputtering target, including the following steps: S100: manually press molding: putting ruthenium powder into a mold, and manually pressurizing the ruthenium powder to form the ruthenium powder into a relative density is a first preformed target with a first preset density; S200: vacuum hot pressing, placing the first stage target together with the mold into a vacuum hot press for processing to obtain a second preformed target with a relative density of the second preset density The preformed target material, and the second preset density is bigger than the first preset density; S300: hot isostatic pressing, the second preformed target material is put into the hot isostatic pressing for processing, and the relative density of the third preformed target is obtained. Assuming the density of the forming target, the third preset density is bigger than the second preset density, and the third preset density is exceeded 99.5%. The preparation method of the ruthenium rotary sputtering target disclosed in this invention can effectively solve the problem of volume shrinkage in the target forming process, so that the shape of the target is better controllable, which improving the stability of the target during the sputtering process and the film quality.

### CROSS REFERENCE TO RELATED APPLICATION

This patent application claims the benefit and priority of Chinese Patent Application No. 202210943255.6 filed on Aug. 8, 2022 the disclosure of which is incorporated by reference herein in its entirety as part of the present application.

### TECHNICAL FIELD

The invention relates to the technical field of powder metallurgy, in particular to method to manufacture ruthenium rotary target.

### TECHNICAL BACKGROUND

Ruthenium thin films are widely used in the fields of electronics, electricity and catalysis due to their unique physical and chemical properties. Ruthenium thin films are an important intermediate material for perpendicular magnetic recording media. The main function is to reduce the lattice mismatch stress between the upper and lower layers. Noise, but also has the effect of enhancing thermal stability, and ruthenium sputtering targets are mainly used to deposit ruthenium thin films in the physical magnetron sputtering process.

At present, there are few document about the ruthenium rotary target, document 1 (Patent: CN104032270A) discloses a method for preparing a ruthenium alloy planar sputtering target with a density of more than 99.5% by vacuum hot pressing, but the patent does not involve the process of rotary target; document 2 (Patent: CN107771224B) discloses a process and flow of a rotary sputtering target, but the patent does not involve the case where the raw material is ruthenium powder. Now the sputtering targets using ruthenium as raw materials are generally mainly planar targets, but the planar sputtering targets usually have the following disadvantages during deposition: 1) The fixed etching area leads to the limitation of the available range of the target, making the utilization rate of flat sputtering targets is usually low (up to 40%); 2) In the process of target etching, sputtering areas with different depths will cause differences in sputtering rates, which will ultimately affect the uniformity of target sputtering film formation sex. This phenomenon is particularly evident during the deposition of high-quality functional thin films. 3) Since the sputtering area is fixed, during the coating process, some insulating materials will be deposited on the surface of the non-etched area, which will cause the accumulation of electrons and lead to arcing on the surface, which may cause pollution of the deposited film in light cases, or direct interruption in heavy cases. The process of sputter deposition. Therefore, rotary sputtering targets using ruthenium as raw materials have gradually appeared. However, in the preparation process of rotary sputtering targets using ruthenium as raw materials, the problem of volume shrinkage of the target material is very likely to occur due to the process and other reasons, resulting in forming the target material. The shape of the product is uncontrollable, which greatly reduces the yield of the product.

Therefore, how to provide a preparation method of a ruthenium rotary sputtering target can not only effectively solve the problem of volume shrinkage in the target forming process, improve the shape controllability and yield of the formed target, but also effectively improve the target. The stability and film formation quality during the sputtering process are technical problems that those skilled in the art need to solve urgently.

### INVENTION CONTENT

In view of this, the purpose of the present invention is a preparation method of a ruthenium rotary sputtering target, which can effectively solve the problem of volume shrinkage in the target forming process, not only can improve the shape controllability and yield of the forming target, but also improve the stability of the target material during the sputtering process and the quality of the film formation.

To achieve the above object, the present invention provides the following technical solutions:

A method to manufacture ruthenium rotary target, comprising the following steps:
S100: manual press molding: put the ruthenium powder into a mold, and manually pressurize the ruthenium powder, so that the ruthenium powder is molded into a first pre-formed target with a relative density of a first preset density;
S200: Vacuum hot pressing: place the first preformed target together with the mold into a vacuum hot press machine to process to obtain a second preformed target with a relative density of a second preset density. The density is bigger than the first preset density;
S300: Hot isostatic pressing: Place the second preformed target material in a hot isostatic pressing machine for processing to obtain a formed target material with a relative density of a third predetermined density, where the third predetermined density is bigger than the second preformed target Set the density, and the third preset density is exceeded 99.5%.

Preferably, in the step S100, 4 kg-6 kg of ruthenium powder is put into the mold, and the manually applied pressure on the ruthenium powder is 0.8 tons to 1.2 tons.

Preferably, in the step S200, the mold includes an inner mold and an outer mold, a cavity for placing the ruthenium powder is formed between the inner mold and the outer mold, and the outer mold is made of graphite block, the inner mold is made of stainless steel, and graphite paper is adhered to the inner wall of the outer mold and the outer wall of the inner mold.

Preferably, in the step S200, the processing steps of the first preformed target in the vacuum hot press include:
S201: Put the first preformed target material together with the mold into the vacuum hot press machine;
S202: Control the vacuum degree of the inner cavity of the vacuum hot press to be a preset vacuum degree;
S203: Control the temperature of the inner cavity of the vacuum hot press to increase the temperature uniformly to 700° C.-900° C. within a first preset time, and then keep the temperature for a second preset time;
S204: Applying a pressure of a preset pressure value to the first preformed target;
S205: After cooling the first preformed target to below 30° C., demolding to obtain the second preformed target.

Preferably, in the step S202, the preset vacuum degree is a vacuum degree less than 10⁻⁴ Pa;

In the step S203, the first preset time is 30 mins to 50 mins, and the second preset time is 1.5 hours to 4.5 hours;

In the step S204, the preset pressure value is 25 tons to 30 tons.

Preferably, the step S204 is specifically as follows: applying a pressure of a preset pressure value to the first preformed target and maintaining the pressure for 0.5 hours to 2 hours.

Preferably, the step S204 is specifically: pressurizing the first preformed target material at a constant speed to the preset pressure value.

Preferably, between the step S200 and the step S300, the method further includes wrapping a titanium can on the outside of the second preformed target, so that the second preformed target is placed in the titanium can inside and the inside of the titanium can is evacuated to less than 10⁻⁴ Pa.

Preferably, in the step S300, the processing steps of the second preformed target in the hot isostatic pressing machine include:
S301: Heating the second preformed target material at a constant speed to 1200° C.-1500° C.;
S302: Pressurize the second preformed target material at a constant speed to 180 Pa-210 Pa;
S303: Keep the second pre-formed target material under heat and pressure for 4 h-6 h until the second pre-formed target material is formed into a formed target material with a relative density of 99.5%.

Preferably, step S304 is also included, the titanium can is removed after the temperature of the forming target is lowered to below 30° C.

Preferably, the first preset density is 25-35%;

The second preset density is 60-70%.

Preferably, the step S100 further includes a raw material preparation step, selecting ruthenium powder with a purity of 3N5 or more as the raw material, uniformly stirring the ruthenium powder, and storing the ruthenium powder in a vacuum seal.

Preferably, in the raw material preparation step, the tap density, particle size distribution and particle specific surface area of the ruthenium powder are detected, and the tap density, particle size distribution and particle specific surface area of the ruthenium powder are obtained. physical parameters.

Preferably, in the raw material preparation step, the ruthenium powder is put into a stirrer for uniform stirring, and the stirring time of the ruthenium powder is 15 mins-30 mins.

Preferably, in the step of preparing the raw materials, the ruthenium powder is divided into 4 kg/bag-6 kg/bag, and the ruthenium powder is vacuum-sealed and stored.

Preferably, step S400 is also included: machining to remove defects and machining tolerance of the formed target.

Preferably, the method further includes step S500: quality inspection, performing inspection and analysis on the forming target to obtain the grain size, phase distribution and impurity element content of the forming target.

Preferably, step S600 is further included: polishing treatment to remove mechanical scratches and fingerprints of the forming target, so that the smoothness of the forming target is within a preset smoothness range.

Preferably, step S700 is further included: packing processing, performing packing processing on the shaped target material.

Preferably, in the step S600, the finish of the forming target includes inner surface finish and outer surface finish, the inner surface finish is less than 20 RA, and the outer surface finish is less than 35 RA.

Preferably, the forming target material is a hollow cylindrical structure;

The height of the shaped target is 90 mm-110 mm, the outer diameter of the shaped target is 140 mm-150 mm, and the inner diameter of the shaped target is 125 mm-135 mm.

It can be seen from the above technical solutions that in the preparation process of the ruthenium rotary sputtering target material, the ruthenium powder is first put into the mold, and the ruthenium powder is manually pressurized, so that the ruthenium powder is formed into a relative density of the first preset density and the first preformed target; then put the first preformed target together with the mold into a vacuum hot press to process to obtain a second preformed target whose relative density is the second preset density, and the second preset density is bigger than the first preset density; finally, the second preformed target material is put into the hot isostatic pressing machine for processing, to obtain a formed target material with a relative density of a third preset density, and the third preset density is greater than the second preset density, the third preset density is exceeded 99.5%.

Compared with the current methods, in the preparation method of the ruthenium rotary sputtering target disclosed in the embodiment of the present invention, the vacuum hot pressing step can further hot press the first preformed target on the basis of manual pressing, so that the first preformed target is processed in a vacuum hot press to obtain a second preformed target with a relative density of the second preset density, which can effectively solve the volume shrinkage in the target forming process in the subsequent thermal processing process. That makes the shape of the forming target more controllable, so that the yield of the forming target can be greatly improved.

During the use of the rotary sputtering target, the permanent magnet in the center is fixed, and the external target remains in a rotating state. Therefore, the etching of the target is always in a non-fixed and uniform state, which greatly improves the molding process. The utilization rate of the target material, and because the entire target surface is in the etched area, the electron accumulation and arcing phenomenon in the flat target are greatly reduced, which effectively improves the stability and film formation quality of the formed target material during the sputtering process.

### Attached Photos

To illustrate the embodiments of the present invention or the technical solutions in the prior art more clearly, the following briefly introduces the accompanying drawings that need to be used in the description of the embodiments or the prior art. Obviously, the drawings in the following description are only It is an embodiment of the present invention. For those of ordinary skill in the art, other drawings can also be obtained according to the provided drawings without creative efforts.

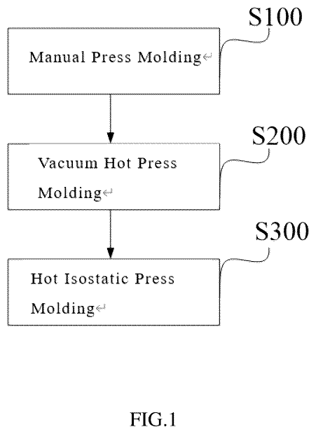

FIG. 1 is a schematic flowchart of a method for preparing a ruthenium rotary sputtering target disclosed in an embodiment of the present invention;

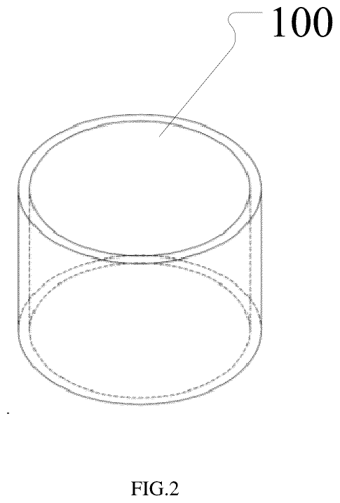

FIG. 2 is a schematic three-dimensional structure diagram of a single-section forming target disclosed in an embodiment of the present invention;

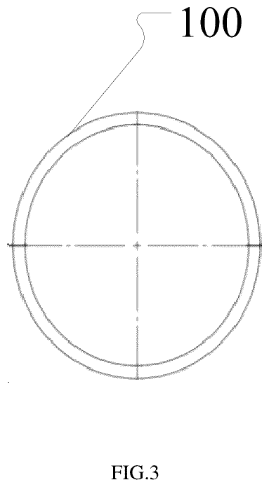

FIG. 3 is a schematic front view structure diagram of a single-section forming target disclosed in an embodiment of the present invention;

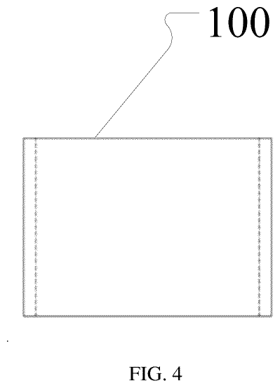

FIG. 4 is a schematic top-view structural diagram of a single-section forming target disclosed in an embodiment of the present invention;

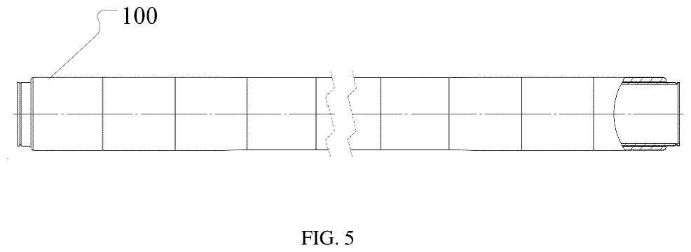

FIG. 5 is a schematic top-view structural diagram of a multi-section shaped target disclosed in an embodiment of the present invention;

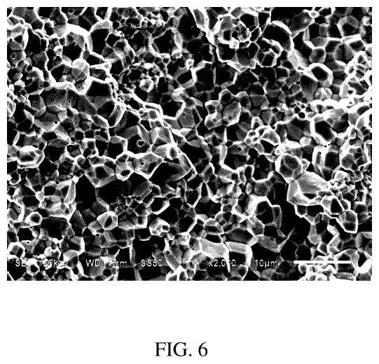

FIG. 6 is a schematic structural diagram of a cross-sectional scanning electron microscope image of a formed target at a magnification of 2000 according to an embodiment of the present invention.

Among them, the names of the parts are as follows:
100 is the forming target.

### DETAILED ACHIEVE WAYS

In view of this, the core of the present invention is to provide a preparation method of a ruthenium rotary sputtering target, which can not only effectively solve the problem of volume shrinkage in the target forming process, but also improve the shape controllability and yield of the formed target. It can also effectively improve the stability of the target material during the sputtering process and the quality of the film formation.

In order to make those skilled in the art better understand the solution of the present invention, the present invention will be further described in detail below with reference to the accompanying drawings and specific embodiments, please refer to FIG. 1 to FIG. 6.

Please refer to FIG. 1, the method to manufacture ruthenium rotary target disclosed in the embodiment of the present invention includes the following steps:
S100: manual pressure molding: put the ruthenium powder into the mold, and manually pressurize the ruthenium powder, so that the ruthenium powder is formed into a first pre-formed target with a relative density of a first preset density;
S200: Vacuum hot pressing: placing the first preformed target material together with the mold into a vacuum hot pressing machine for processing to obtain a second preformed target with a relative density of a second preset density, and the second preset density is greater than the first preformed target preset density;
S300: Hot isostatic pressing: placing the second preformed target material in a hot isostatic pressing machine for processing to obtain a formed target material with a relative density of a third predetermined density, where the third predetermined density is greater than the second predetermined density, and the third preset density is exceeded 99.5%.

In the method to manufacture ruthenium rotary target, firstly, the ruthenium powder is put into the mold, and the ruthenium powder is manually pressurized, so that the ruthenium powder is formed into a first pre-formed target with a relative density of the first preset density; Then, put the first preformed target material together with the mold into a vacuum hot press for processing to obtain a second preformed target material with a relative density of the second preset density, and the second preset density is greater than the first preset density; The second preformed target material is put into the hot isostatic pressing machine for processing to obtain a formed target material with a relative density of a third predetermined density, the third predetermined density is greater than the second predetermined density, and the third predetermined density is exceeded 99.5%.

Compared with the current method, the method to manufacture ruthenium rotary target disclosed in the embodiment of the present invention, the vacuum hot pressing forming step can further hot press the first preformed target on the basis of manual pressing. So that the first preformed target is processed in a vacuum hot press to obtain a second preformed target with a relative density of the second preset density, which can effectively solve the volume shrinkage during the target forming process in the subsequent thermal processing process. The problem makes the shape of the forming target more controllable, so that the yield of the forming target can be greatly improved.

During the use of the rotary sputtering target, the permanent magnet in the center is fixed, and the external target remains in a rotating state. Therefore, the etching of the target is always in a non-fixed and uniform state, which greatly improves the molding process. The utilization rate of the target material, and because the entire target surface is in the etched area, the electron accumulation and arcing phenomenon in the flat target are greatly reduced, which effectively improves the stability of the formed target material during the sputtering process and the film formation quality.

It should be explained that the relative density is obtained with dividing the density of the semi-finished or finished target by the theoretical density, wherein the theoretical density of ruthenium is 12.2 g/m³.

Which means that the relative density of the first preformed target is the actual density of the first preformed target divided by the theoretical density; the relative density of the second preformed target is the actual density of the second preformed target divided by the theoretical density; The relative density of the material is the actual density of the formed target divided by the theoretical density.

It should be noted that, in the manual pressure forming step disclosed in the embodiment of the present invention, 4 kg-6 kg of ruthenium powder needs to be put into the mold, and the manually applied pressure on the ruthenium powder is 0.8-1.2 tons.

As a preferred embodiment, in the manual pressure forming step disclosed in the embodiment of the present invention, the manual pressure applied to the ruthenium powder is preferably 1 ton.

The embodiments of the present invention do not specifically limit the structure and material of the mold, as long as the structure meets the requirements for use of the present invention, it is within the protection scope of the present invention.

As a preferred embodiment, the mold disclosed in the embodiment of the present invention includes an inner mold and an outer mold, wherein a cavity for placing ruthenium powder is formed between the inner mold and the outer mold, the outer mold is made of graphite block, and the inner mold is made of made of stainless steel, and graphite paper is adhered to the inner wall of the outer mold and the outer wall of the inner mold.

It should be noted that when the ruthenium powder is manually pressurized, the ruthenium powder must be pressurized with a vertical downward pressure. This setting can effectively prevent the first cause of wrinkling of the graphite paper during the process of manually applying pressure. The problem of surface defects of pre-formed targets further improves the yield of formed targets.

In the method to manufacture ruthenium rotary target disclosed in the embodiment of the present invention, in the vacuum hot pressing forming step, the processing step of the first preformed target in the vacuum hot pressing machine includes:
S201: put the first preformed target material together with the mold into the vacuum hot press; S202: control the vacuum degree of the inner cavity of the vacuum hot press to be a preset vacuum degree; S203: control the temperature of the vacuum hot press inner cavity during the first preset time, the temperature is uniformly heated to 700° C.-900° C. and then kept for a second preset time; S204: apply a pressure of a preset pressure value to the first preformed target; S205: cool the first preformed target until the temperature is below 30° C., demolded and obtain a second preformed target.

The above processing steps of vacuum hot pressing can effectively solve the problem of volume shrinkage in the target forming process, so that the shape of the target can be more controllable, thereby further stabilizing the yield of the formed target.

The scope of the vacuum degree is not specifically limited in the embodiments of the present invention, as long as the structures that meet the use requirements of the present invention are within the protection scope of the present invention.

As a preferred embodiment, the preset vacuum degree disclosed in the embodiment of the present invention is preferably a vacuum degree less than 10⁻⁴ Pa.

The embodiments of the present invention do not specifically limit the first preset time and the second preset time, as long as the structures that meet the usage requirements of the present invention are within the protection scope of the present invention.

As a preferred embodiment, the first preset time disclosed in the embodiment of the present invention is preferably 30 min to 50 min, and the second preset time is preferably 1.5 hours to 4.5 hours.

As a more preferred embodiment, the first preset time disclosed in the embodiment of the present invention is preferably 45 minutes, and the second preset time is 3 hours.

The embodiment of the present invention does not specifically limit the preset pressure value, as long as the structure that meets the use requirements of the present invention is within the protection scope of the present invention.

As a preferred embodiment, the preset pressure value disclosed in the embodiment of the present invention is preferably 25 tons to 30 tons.

As a more preferred embodiment, the preset pressure value disclosed in the embodiment of the present invention is 26 tons.

It should be noted that, in step S204, a pressure of a preset pressure value needs to be applied to the first preformed target, and the temperature is maintained for 0.5 hours to 2 hours.

As a preferred embodiment, in step S204, a pressure of a preset pressure value needs to be applied to the first preformed target, and the temperature is maintained for 1 hour.

In the preparation method of the ruthenium rotary sputtering target disclosed in the embodiment of the present invention, between the vacuum hot pressing forming step and the hot isostatic pressing forming step, the method further comprises: wrapping a titanium envelope on the outside of the second preformed target, so that the second preformed target material is placed in the titanium can, and the titanium can is evacuated to less than 10⁻⁴ Pa. In this way, since the structure of the titanium can is used in the hot isostatic pressing step, the change of the shape of the target material under high temperature and high pressure can be effectively controlled, so that the controllability of the shape of the target material can be further improved, and at the same time, the relative density of the formed target can also be further improved

Wherein, in the hot isostatic pressing, the processing steps of the second preformed target in the hot isostatic pressing machine include: S301: heating the second preformed target at a constant speed to 1200° C.-1500° C.; S302: the second preformed target is pressurized at a constant speed to 180 Pa-210 Pa; S303: the second preformed target is kept under pressure for 4 h-6 h until the second preformed target is formed into a formed target with a relative density of 99.5%.

As a preferred embodiment, in S301 disclosed in the embodiment of the present invention, preferably the second pre-formed target is heated to 1375° C. at a constant speed, the second pre-formed target is pressurized to 196 Pa at a constant speed and hold the temperature and pressure for 5 h.

Wherein, in the preparation method of the ruthenium rotary sputtering target disclosed in the embodiment of the present invention, in the step of static pressing. It also includes step S304, after the temperature of the forming target is lowered to below 30° C., the titanium can is removed by electrical discharge machine.

As a preferred embodiment of the present invention, the first preset density disclosed in the embodiment of the present invention is 25-35%; the second preset density is 60-70%.

As a more preferred embodiment, the first preset density disclosed in the embodiment of the present invention is 30%; the second preset density is 65%.

It should be noted that the method for preparing a ruthenium rotary sputtering target disclosed in the embodiment of the present invention further includes a raw material preparation step before the manual pressure forming step, wherein the raw material preparation step is specifically: selecting ruthenium with a purity of 3N5 or higher. The ruthenium powder is used as a raw material, and the ruthenium powder is uniformly stirred. After stirring, a homogeneous and dispersed powder raw material can be obtained, and the ruthenium powder is stored in a vacuum seal.

Specifically, in the raw material preparation step, it is necessary to detect the tap density, particle size distribution and particle specific surface area of the ruthenium powder, and obtain the physical parameters of the tap density, particle size distribution and particle specific surface area of the ruthenium powder. In this way, the height of the forming target can be easily calculated.

Specifically, in the raw material preparation step, the ruthenium powder needs to be sub packaged according to 4 kg/bag-6 kg/bag, and the ruthenium powder should be stored in a vacuum seal.

The method to manufacture ruthenium rotary target disclosed in the embodiment of the present invention further includes step S400: machining, removing defects and machining tolerance of the formed target 100, so that the formed target 100 conforms to a preset specification and size requirement.

The method to manufacture ruthenium rotary target disclosed in the embodiment of the present invention further includes step S500: quality inspection, detecting and analyzing the formed target material 100 to obtain the grain size, phase distribution and impurities of the formed target material 100 element content. In this way, further screening of qualified shaped targets 100 can be achieved.

The method to manufacture ruthenium rotary target disclosed in the embodiment of the present invention further includes step S600: polishing, removing mechanical scratches and fingerprints of the forming target 100, so that the smoothness of the forming target 100 is within a preset smoothness range in order to further improve the quality of the forming target 100.

It should be noted that, in the polishing step, the finish of the forming target 100 includes inner surface finish and outer surface finish, wherein the inner surface finish is preferably less than 20 RA, and the outer surface finish is preferably less than 35 RA.

The method to manufacture ruthenium rotary target disclosed in the embodiment of the present invention further includes step S700: packing processing and packing the shaped target material 100.

Referring to FIGS. 2 to 4, the formed target 100 prepared by the method for preparing a ruthenium rotary sputtering target disclosed in the embodiment of the present invention has a hollow cylindrical structure, wherein the height of the formed target 100 is preferably 90 mm-110 mm, the outer diameter of the forming target 100 is preferably 140 mm-150 mm, and the inner diameter of the forming target 100 is preferably 125 mm-135 mm.

As a more preferred embodiment, the height of the molding target 100 is preferably 100 mm, the outer diameter of the molding target 100 is preferably 149 mm, and the inner diameter of the molding target 100 is preferably between 135 mm.

Referring to FIG. 5, the ruthenium rotary sputtering target disclosed in the embodiment of the present invention may be composed of a multi-section shaped target 100.

Preferably, the ruthenium rotary sputtering target disclosed in the embodiment of the present invention is composed of 19-part targets 100.

The single-section ruthenium rotary sputtering target with a relative density greater than 99.5% disclosed in the embodiment of the present invention, wherein the purity of ruthenium is greater than 99.5%, the impurity content of the single-section rotary sputtering target material is lower than 1000 ppm, and the main impurity elements, C<200 ppm, N<100 ppm, O<350 ppm, S<50 ppm, where C is carbon, N is nitrogen, O is oxygen, and S is sulfur.

Please refer to FIG. 6, which is a scanning electron microscope (SEM) image of the cross-section of the ruthenium spin sputtering target at 2000 times.

As a specific embodiment, the preparation method of the material rotary sputtering target disclosed in the embodiment of the present invention includes:
Raw material preparation: select ruthenium powder with a raw material purity of 3N5 or more, and mix it uniformly as raw material;
Manual press molding: put the ruthenium powder into the mold, and manually pressurize the ruthenium powder, so that the ruthenium powder is molded into the first preformed target with a relative density of 25%-35%;
Vacuum hot pressing molding: after filling 5 Kg-6 Kg ruthenium powder into a mold attached with graphite paper on the surface, the first preformed target material and the mold are put into a vacuum hot pressing machine for processing, and the temperature of the vacuum hot pressing machine is controlled to be 800° C.-900° C., the pressure is 25 tons-30 tons, in order to avoid surface defects and damage of the target material, it should be ensured that the graphite paper is not damaged or wrinkled, and at the same time, a vertical downward pressure should be applied in the vacuum hot press;
Hot isostatic pressing: demold the preformed target after vacuum hot pressing, seal it into the prepared titanium can, vacuumize it and put it into the hot isostatic pressing machine to control the temperature 1300-1400° C., and the pressure is 180-200 MPa. In order to avoid irregular shrinkage of the target, the titanium can should be built strictly according to the size of the target, and the gap should be filled with 1 mm thick graphite paper;
Machining: remove the can of the target after hot isostatic pressing and process the target to the final size through lathes, grinders and other processes. In order to prevent the size from exceeding the control line, at least 0.5 mm machining allowance should be reserved after the lathe;
Quality inspection: inspect the crystal structure, lattice size, impurity element content, appearance and size of the target sample to meet the shipping requirements;
Polishing treatment: remove mechanical scratches and fingerprints of the forming target, so that the finish of the forming target is within the preset smoothness range.
Packing: after the operator polishes the plastic by manual, it is packed into a pre-prepared carton for packing.

In the description of this application, it should be noted that the terms “center”, “upper”, “lower”, “left”, “right”, “vertical”, “horizontal”, “inner”, “outer”, etc. The indicated orientation or positional relationship is based on the orientation or positional relationship shown in the accompanying drawings, which is only for the convenience of describing the present application and simplifying the description, rather than indicating or implying that the indicated device or element must have a specific orientation or a specific orientation. construction and operation, and therefore should not be construed as limitations on this application. Furthermore, the terms “first”, “second”, and “third” are used for descriptive purposes only and should not be construed to indicate or imply relative importance.

Unless otherwise expressly specified and limited, the terms “installed”, “connected” and “connected” should be understood in a broad sense, for example, it may be a fixed connection, a detachable connection, or an integral connection; it may be a mechanical connection, can also be an electrical connection; it can be a direct connection, or an indirect connection through an intermediate medium, or an internal connection between two components. For those of ordinary skill in the art, the specific meanings of the above terms in this application can be understood in specific situations.

The above description of the disclosed embodiments enables any person skilled in the art to make or use the present invention. Various modifications to these embodiments will be readily apparent to those skilled in the art, and the generic principles defined herein may be implemented in other embodiments without departing from the spirit or scope of the invention. Thus, the present invention is not intended to be limited to the embodiments shown herein but is to be accorded the widest scope consistent with the principles and novel features disclosed herein.

1. A method to manufacture ruthenium rotary target, which is followed the below characterized steps:
S100: putting a ruthenium powder into a mold, and manually pressurize the ruthenium powder, so that the ruthenium powder is molded into a first pre-formed target with a relative density of a first preset density;
S200: Vacuum hot pressing: placing the first preformed target together with the mold into the vacuum hot press machine for a second preformed target with a relative density of a second preset density; the second preset density is bigger than the first preset density;
S300: Hot isostatic pressing: placing the second preformed target material in a hot isostatic pressing machine for a formed target material with a relative density of a third preset density; the third preset density is bigger than the second preset density, and the third preset density is exceeded 99.5%.

2. The method to manufacture ruthenium rotary target according to claim 1, wherein in the step S100, 4 kg-6 kg of ruthenium powder is put into the mold, and the ruthenium powder is manual force, the applied pressure is 0.8 tons-1.2 tons.

3. The method to manufacture ruthenium rotary target according to claim 1, wherein in the step S200, the mold comprises an inner mold and an outer mold, and the inner mold and the outer mold formed a cavity for placing the ruthenium powder, the outer mold is made of graphite block, the inner mold is made of stainless steel, and an extra graphite paper is adhered to the inner wall of the outer mold and the outer wall of the inner mold.

4. The method to manufacture ruthenium rotary target according to claim 1, wherein in the step S200, the process step of the first preformed target in the vacuum hot press machine comprises the following steps:
S201: Put the first preformed target material together with the mold into the vacuum hot press machine;
S202: Control the vacuum degree of the inner cavity of the vacuum hot press machine to be a preset vacuum degree;
S203: Control the temperature of the inner cavity of the vacuum hot press machine to increase the temperature uniformly to 700° C.-900° C. within a first preset time, and then keep the temperature for a second preset time;
S204: Applying a pressure of a preset pressure value to the first preformed target;
S205: After cooling the first preformed target to below 30° C., demolding to obtain the second preformed target.

5. The method to manufacture ruthenium rotary target according to claim 4, wherein in the step S202, the preset vacuum degree is a vacuum degree less than 10⁻⁴ Pa;
in the step S203, the first preset time is 30 mins to 50 mins, and the second preset time is 1.5 hours to 4.5 hours; and
in the step S204, the preset pressure value is 25 tons to 30 tons.

6. The method to manufacture ruthenium rotary target according to claim 4, wherein the step S204 is specifically as follows: applying a pressure of a preset pressure value to the first pre-formed target and keeping the temperature of the target; press for 0.5 hours-2 hours.

7. The method to manufacture ruthenium rotary target according to claim 4, wherein the step S204 is specifically: pressurizing the first preformed target at a constant speed to the preset pressure value.

8. The method to manufacture ruthenium rotary target according to claim 1, characterized in that, between the step S200 and the step S300, the method further comprises: wrapping the second preformed target with a layer of titanium can, so that the second preformed target material is placed in the titanium can, and the titanium can is evacuated to less than 10⁻⁴ Pa.

9. The method to manufacture ruthenium rotary target according to claim 8, wherein in the step S300, the processing step of the second preformed target in the hot isostatic pressing machine include:
S301: heating the second preformed target material at a constant speed to 1200° C.-1500° C.;
S302: pressurizing the second preformed target material at a constant speed to 180 Pa-210 Pa;
S303: keeping the second pre-formed target material under heat and pressure for 4 h-6 h until the second pre-formed target material is formed into a formed target material with a relative density of 99.5%.

10. The method to manufacture ruthenium rotary target according to claim 9, further comprising step S304, the titanium can is removed after the temperature of the formed target is lowered to below 30° C.

11. The method to manufacture ruthenium rotary target according to claim 1, wherein the first preset density is 25-35%, and the second preset density is 60-70%.

12. The method to manufacture ruthenium rotary target according to claim 1, characterized in that, before the step S100, it further comprises a raw material preparation step, selecting ruthenium powder with a purity of 3N5 or more as a raw material, and uniformly distributing the ruthenium powder Stir, and store the ruthenium powder in a vacuum seal.

13. The method to manufacture ruthenium rotary target according to claim 12, characterized in that, in the raw material preparation step, the tap density, particle size distribution and particle specific surface area of the ruthenium powder are detected and obtain the physical parameters of the tap density, particle size distribution and particle specific surface area of the ruthenium powder.

14. The method to manufacture ruthenium rotary target according to claim 12, characterized in that, in the raw material preparation step, the ruthenium powder is put into a stirrer for uniform stirring; the stirring time is 15 min-30 min.

15. (canceled)

16. The method to manufacture ruthenium rotary target according to claim 1, further comprising step S400: machining to remove defects and machining tolerance of the formed target.

17. The method to manufacture ruthenium rotary target material according to claim 1, further comprising step S500: quality inspection, performing detection and analysis on the formed target material to obtain the crystallinity of the formed target material particle size, phase distribution and impurity element content.

18. The method to manufacture ruthenium rotary target according to claim 1, further comprising step S600: polishing, removing machine scratches and fingerprints on the formed target, so that the final target is within the preset finish range.

19. The method to manufacture ruthenium rotary target according to claim 1, further comprising step S700: packing processing, performing packing processing on the shaped target.

20. The method to manufacture ruthenium rotary target according to claim 17, characterized in that, in the step S600, the smoothness of the shaped target includes inner surface smoothness and outer surface smoothness; the inner surface finish is less than 20 RA and the outer surface finish is less than 35 RA.

21. The method to manufacture ruthenium rotary target according to claim 1, wherein the shaped target is a hollow cylindrical structure; and
wherein the height of the shaped target is 90 mm-110 mm, the outer diameter of the shaped target is 140 mm-150 mm, and the inner diameter of the shaped target is 125 mm-135 mm.
